(19) United States
(12) Patent Application Publication
(10) Pub. No.: US 2012/0000504 A1
(43) Pub. Date: Jan. 5, 2012

(54) DOUBLE SIDED TAPE

(76) Inventors: Bruce Bengtson, Woodbury, MN (US); Brian E. Cohen, Perrysburg, OH (US); Yaodong Gan, Whitehouse Station, NJ (US); John Paul Ishioye, Perrysburg, OH (US); Richard S. Malik, JR., Rossford, OH (US); Sumanth Varma Lokanath, Monclova, OH (US); Rui Xiao, Sylvania, OH (US)

(21) Appl. No.: 13/172,311

(22) Filed: Jun. 29, 2011

Related U.S. Application Data
(60) Provisional application No. 61/360,234, filed on Jun. 30, 2010.

(51) Int. Cl. H01L 31/05; B23P 11/00; B32B 27/36; C09J 7/02; B32B 7/02

(52) U.S. Cl. 136/244; 428/354; 428/216; 428/334; 428/335; 29/428

(57) ABSTRACT

A double sided tape without pin holes has a plurality of flexible support and pressure sensitive adhesive layers.

### CLAIM OF PRIORITY

This application claims priority under 35 U.S.C. §119(e) to U.S. Provisional Patent Application Ser. No. 61/360,234 filed on Jun. 30, 2010, which is hereby incorporated by reference in its entirety.

### TECHNICAL FIELD

This invention relates to a double sided tape that is robust against pin holes to have high dielectric breakdown voltage is disclosed. The tape has a plurality of flexible support and pressure sensitive adhesive layers.

### BACKGROUND

Materials with pressure sensitive adhesive surfaces can be used in electrical components. Known adhesive materials may have unacceptable low breakdown voltages and materials may have pin holes filled with air, which can lead to dielectric breakdown of trapped air pocket and cause arcing failures. This may render electrical components unreliable and unsafe.

### DESCRIPTION OF DRAWINGS

FIG. 1 is a schematic of a photovoltaic module.

FIG. 2 is a schematic of a double sided tape.

### DETAILED DESCRIPTION

A photovoltaic module can include a plurality of photovoltaic devices or photovoltaic cells formed on a substrate. Each photovoltaic cell can include a transparent conductive layer formed adjacent to a substrate, a semiconductor window layer adjacent to the transparent conductive layer, and a semiconductor absorber layer adjacent to the semiconductor window layer. Each photovoltaic cell can include a back contact adjacent to the semiconductor absorber layer. The photovoltaic cell back contacts of the plurality of photovoltaic cells can be electrically connected by any suitable configuration of electrical conductors (including, for example, two lead foils) to electrically connect the photovoltaic cells to at least one positive bus and one negative bus. An electrically insulating material can be included between the conductors (such as the lead foils) and the back contacts to prevent a short circuit. One example of a suitable electrically insulating material is an electrically insulating tape layer. The tape layer can have a double sided adhesive tape layer.

To achieve higher breakdown voltage and better electrical insulation of conductors in a photovoltaic module, a double sided tape for use in photovoltaic modules has been developed. With the proper composition and thickness, the probability of the pin holes or thinning can be greatly reduced or eliminated. The double sided tape's composite dielectric breakdown voltage can be over 16 kV. Double sided tape can be used as the insulator in solar energy industry. Insulators can suffer from the phenomenon of electrical breakdown. When any voltage applied across a length of insulating substance exceeds a threshold breakdown field for that substance, the insulator will lose its insulating properties. The electrical breakdown of insulators can result in power system failure.

Breakdown voltage is a characteristic of an insulator that defines the maximum voltage difference that can be applied across the material before the insulator collapses and conducts. In solid insulating materials, this usually creates a weakened path within the material by creating permanent molecular or physical changes by the sudden current. A multilayer composite tape can have a dielectric breakdown voltage over 16 kV.

In one aspect, a double sided tape can include a first pressure sensitive adhesive layer including a first pressure sensitive adhesive side and a second pressure sensitive adhesive side. The first and second pressure sensitive adhesive sides can include a pressure sensitive adhesive. The double sided tape can include a first flexible support layer including a first support side and a second support side. The first support side can be layered adjacent to the first pressure sensitive adhesive side of the first pressure sensitive adhesive layer. The double sided tape can include a second pressure sensitive adhesive layer including a first pressure sensitive adhesive side and a second pressure sensitive adhesive side. The first and second pressure sensitive adhesive sides can include the pressure sensitive adhesive. The first pressure sensitive adhesive side of the second pressure sensitive adhesive layer can be layered adjacent to the second support side of the first flexible support layer.

The double sided tape can include a second flexible support layer comprising a first support side and a second support side. The first support side of the second flexible support layer can be adjacent to the second pressure sensitive adhesive side of the second pressure sensitive adhesive layer. The double sided tape can include a third pressure sensitive adhesive layer including a first pressure sensitive adhesive side and a second pressure sensitive adhesive side. The first and second pressure sensitive adhesive sides can include the pressure sensitive adhesive. The first pressure sensitive adhesive side of the third pressure sensitive adhesive layer can be layered adjacent to the second support side of the second flexible support layer.

The pressure sensitive adhesive can include a low surface energy pressure sensitive adhesive. The flexible support can include any suitable flexible support material. The flexible support can include a polymeric material, a plastic material, a fibrous material, or combinations thereof, or any other suitable material. The flexible support can include a polyethylene terephthalate. The double sided tape can have a dielectric breakdown voltage greater than about 5 kV. The double sided tape can have a dielectric breakdown voltage greater than about 10 kV. The double sided tape can have a dielectric breakdown voltage greater than about 16 kV. The double sided tape can have a dielectric breakdown voltage greater than about 20 kV. The double sided tape and its layers can have any thickness suitable to provide the required dielectric breakdown voltage. For example, the double sided tape can have a thickness between 0.03 mm and 2.0 mm, or between 0.1 mm and 1.0 mm, or between 0.3 mm and 0.8 mm.

The pressure sensitive adhesive layer can have a thickness less than 0.5 mm, less than 0.3 mm, or less than 0.1 mm. The pressure sensitive adhesive layer can have a thickness less than 0.08 mm. The pressure sensitive adhesive layer can have a thickness in the range of 0.01 mm to 0.05 mm, or 0.01 mm to 0.02 mm. The flexible support layer can have a thickness less than 0.5 mm, less than 0.3 mm, or less than 0.1 mm. The flexible support layer can have a thickness in the range of 0.01 mm to 0.08 mm, 0.02 mm to 0.05 mm, or 0.02 mm to 0.03 mm.

In another aspect, a method of manufacturing a double sided tape can include layering a first pressure sensitive adhesive layer, a first flexible support layer, and a second pressure sensitive adhesive layer. The layering can include placing the first support side of the first flexible support layer including a first support side and a second support side adjacent to the first pressure sensitive adhesive side of the first pressure sensitive adhesive layer, which can include a first pressure sensitive adhesive side and a second pressure sensitive adhesive side. The method can include placing the second support side of the first flexible support layer adjacent to the first pressure sensitive adhesive side of the second pressure sensitive adhesive layer including a first pressure sensitive adhesive side and a second pressure sensitive adhesive side. The method can include layering a second flexible support layer adjacent to the second pressure sensitive adhesive layer and a third pressure sensitive adhesive layer adjacent to the second flexible support layer. The layering can include placing the first support side of the second flexible support layer including a first support side and a second support side adjacent to the second pressure sensitive adhesive side of the second pressure sensitive adhesive layer. The method can include placing the first pressure sensitive adhesive side of the third pressure sensitive adhesive layer including a first pressure sensitive adhesive side and a second pressure sensitive adhesive side adjacent to the second support side of the second flexible support layer.

The pressure sensitive adhesive can include a low surface energy pressure sensitive adhesive. The flexible support layer can include a polyethylene terephthalate. The pressure sensitive adhesive layer can have a thickness less than 0.08 millimeter. The pressure sensitive adhesive layer can have a thickness in the range of 0.01 millimeter to 0.02 millimeter. The flexible support layer can have a thickness less than 0.1 millimeter. The flexible support layer can have a thickness in the range of 0.02 millimeter to 0.03 millimeter.

In another aspect, a photovoltaic module can include a transparent conductive layer on a substrate, a first submodule including a first plurality of photovoltaic cells connected in series, and a second submodule including a second plurality of photovoltaic cells connected in series. The first and second submodules can be connected in parallel and contacting the transparent conductive layer through a shared cell. The module can include a strip of tape having a length distributed along a contact region on the first and second submodules.

The strip of tape can include a first pressure sensitive adhesive layer including a first pressure sensitive adhesive side and a second pressure sensitive adhesive side. The first and second pressure sensitive adhesive sides can include a pressure sensitive adhesive. The strip of tape can include a first flexible support layer including a first support side and a second support side and attached adjacent to the second pressure sensitive adhesive side of the first pressure sensitive adhesive layer. The strip of tape can include a second pressure sensitive adhesive layer including a first pressure sensitive adhesive side and a second pressure sensitive adhesive side. The first and second pressure sensitive adhesive sides can include the pressure sensitive adhesive, and the first pressure sensitive adhesive side of the second pressure sensitive adhesive layer can be attached adjacent to the second support side of the first flexible support layer.

The strip of tape can include a second flexible support layer including a first support side and a second support side and attached adjacent to the second pressure sensitive adhesive side of the second pressure sensitive adhesive layer. The strip of tape can include a third pressure sensitive adhesive layer including a first pressure sensitive adhesive side and a second pressure sensitive adhesive side. The first and second pressure sensitive adhesive sides can include the pressure sensitive adhesive, and the first pressure sensitive adhesive side of the third pressure sensitive adhesive layer can be attached adjacent to the second support side of the second flexible support layer.

The photovoltaic module can include a lead foil distributed along the length of the strip of tape, a plurality of parallel bus bars, positioned adjacent and perpendicular to the strip of tape, wherein each one of the plurality of parallel bus bars contacts the lead foil, and a back support adjacent to the bus bars including an access opening for accessing the lead foil. At least one of the pressure sensitive adhesive layers of the strip of tape can include discontinuous stripes. The strip of tape can include a release liner on at least one of the pressure sensitive adhesive layers.

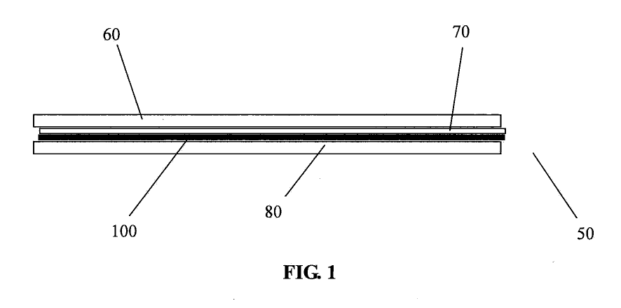

Referring to FIG. 1, photovoltaic module 50 can include superstrate 60, photovoltaic device stack 70, double side tape 100, and substrate 80. Superstrate 60 can include any suitable transparent material, such as glass. Photovoltaic device stack 70 can include a semiconductor window layer, a semiconductor absorber layer, and a back contact. Double side tape 100 can be positioned adjacent to the back contact of photovoltaic device stack 70.

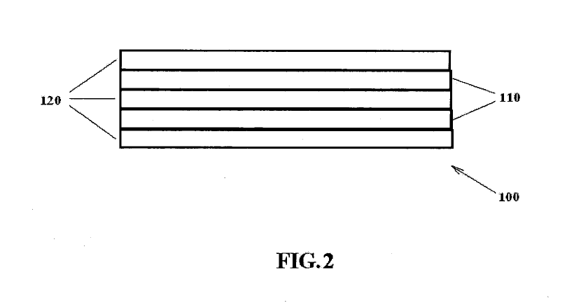

Referring to FIG. 2, double sided tape 100 can have a configuration of pressure sensitive adhesive layer 120/flexible support layer 110/pressure sensitive adhesive layer 120/flexible support layer 110/pressure sensitive adhesive layer 120. By using a stack of pressure sensitive adhesive layer 120 and flexible support layer 110, the probability of the pin holes or thinning can be greatly reduced or eliminated.

Pressure sensitive adhesive layer 120 (PSA, self adhesive, self stick adhesive) is adhesive which forms a bond when pressure is applied to marry the adhesive with the adherent. No solvent, water, or heat is needed to activate the adhesive. It can be used in pressure sensitive tapes, labels, note pads, automobile trim, and a wide variety of other products. The degree of bond can be influenced by the amount of pressure which is used to apply the adhesive to the surface. Surface factors such as smoothness, surface energy, removal of contaminants, etc. are also important to proper bonding. Therefore, PSAs are designed to form a bond and hold flexible support layers to have proper composition and thickness. PSAs typically reduce or lose their tack at cold temperatures and reduce their shear holding ability at high temperatures: specialty adhesives can be included in the present invention to function at high or low temperatures. Pressure sensitive adhesive layer 120 can include any suitable adhesive material on any suitable adhesive substrate. For example, the adhesive substrate can include a polymeric, plastic, or fibrous material. The adhesive material can include any suitable organic or inorganic adhesive material. The adhesive material can include a liquid material, a solid material, or a gel material, or combinations thereof. The adhesive material can include one or more elastomers compounded with one or more tackifiers. Examples of suitable elastomers can include natural rubbers, nitriles, butyl rubbers, acrylics, styrene block copolymers, vinyl ethers, ethylene-vinyl acetate, or silicone rubbers. Examples of suitable tackifiers can include resins such as rosins (e.g., rosin ester), terpenes, aliphatic, cycloaliphatic, and aromatic resins, hydrocarbonated resins, or silicate resins.

Flexible support layer 110 can include a polyethylene terephthalate (PET) or any other suitable material. Polyethylene is a thermoplastic polymer resin of the polyester family and can be used in synthetic fibers. Depending on its processing and thermal history, polyethylene terephthalate may exist both as an amorphous (transparent) and as a semi-crystalline material. The semi crystalline material might appear transparent (spherulites<500 nm) or opaque and white depending on its crystal structure and spherulite size. Its monomer (bis-β-hydroxyterephthalate) can be synthesized by the esterification reaction between terephthalic acid and ethylene glycol with water as a byproduct, or by transesterification reaction between ethylene glycol and dimethyl terephthalate with methanol as a byproduct. Polymerization is through a polycondensation reaction of the monomers (done immediately after esterification/transesterification) with ethylene glycol as the byproduct (the ethylene glycol is directly recycled in production). Given the chemical and physical properties of PET, it can be a good flexible support material for double sided tape 100. Flexible support layer 110 can include other suitable polymer material.

Each pressure sensitive adhesive layer 120 and each flexible support layer 110 can have any suitable thickness. Pressure sensitive adhesive layer can have a thickness of less than 1 mm, less than 0.5 mm, less that 0.2 mm, less than 0.1 mm, less than 0.8 mm, less than 0.05 mm, less than 0.03 mm, less than 0.02 mm, and between 0.01 and 0.02 mm. Flexible support layer 110 can have a thickness of less than 1 mm, less than 0.5 mm, less that 0.2 mm, less than 0.1 mm, less than 0.05 mm, less than 0.03 mm, less than 0.02 mm, between 0.01 and 0.03 mm, or between 0.02 and 0.03 mm.

In some embodiments, the double side adhesive (100 in FIG. 1) facing the back contact of photovoltaic device (70 in FIG. 1) can pull the metal off photovoltaic device. To prevent or mitigate this effect, the double side adhesive facing the back contact can be non continuous to reduce the amount of metal in contact with adhesive and thus reduce potential area affected. One or more spots of adhesive (such as one or more discontinuous spots or stripes) can be sufficient to tack the insulating tape to the module surface. In some embodiments, double sided tape 100 can further include a release liner on one of the adhesive layers to defeat any pull force from an adherence of the adhesive layer 120 to the support layer 110.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. A double sided tape comprising:
a first pressure sensitive adhesive layer comprising a first pressure sensitive adhesive side and a second pressure sensitive adhesive side, wherein the first and second pressure sensitive adhesive sides comprise a pressure sensitive adhesive;
a first flexible support layer comprising a first support side and a second support side, wherein the first support side is layered adjacent to the second pressure sensitive adhesive side of the first pressure sensitive adhesive layer; and
a second pressure sensitive adhesive layer comprising a first pressure sensitive adhesive side and a second pressure sensitive adhesive side, wherein the first and second pressure sensitive adhesive sides comprise the pressure sensitive adhesive, wherein the first pressure sensitive adhesive side of the second pressure sensitive adhesive layer is layered adjacent to the second support side of the first flexible support layer.

2. The double sided tape of claim 1, further comprising:
a second flexible support layer comprising a first support side and a second support side, wherein the first support side of the second flexible support layer is layered adjacent to the second pressure sensitive adhesive side of the second pressure sensitive adhesive layer; and
a third pressure sensitive adhesive layer comprising a first pressure sensitive adhesive side and a second pressure sensitive adhesive side, wherein the first and second pressure sensitive adhesive sides comprise the pressure sensitive adhesive, and the first pressure sensitive adhesive side of the third pressure sensitive adhesive layer is layered adjacent to the second support side of the second flexible support layer.

3. The double sided tape of claim 1, wherein the pressure sensitive adhesive comprises a low surface energy pressure sensitive adhesive.

4. The double sided tape of claim 1, wherein the flexible support layer comprises a polyethylene terephthalate.

5. The double sided tape of claim 1, comprising a dielectric breakdown voltage greater than about 5 kV.

6. The double sided tape of claim 5, comprising a dielectric breakdown voltage greater than about 10 kV.

7. The double sided tape of claim 5, comprising a dielectric breakdown voltage greater than about 16 kV.

8. The double sided tape of claim 5, comprising a dielectric breakdown voltage greater than about 20 kV.

9. The double sided tape of claim 1, wherein each pressure sensitive adhesive layer has a thickness less than 0.08 mm.

10. The double sided tape of claim 9, wherein the pressure sensitive adhesive layer has a thickness in the range of 0.01 millimeter to 0.02 millimeter.

11. The double sided tape of claim 1, wherein the flexible support layer has a thickness less than 0.1 millimeter.

12. The double sided tape of claim 11, wherein the flexible support layer has a thickness in the range of 0.02 millimeter to 0.03 millimeter.

13. A method of manufacturing a double sided tape comprising layering a first pressure sensitive adhesive layer, a first flexible support layer, and a second pressure sensitive adhesive layer, wherein the layering comprises:
placing the first support side of the first flexible support layer comprising a first support side and a second support side adjacent to the first pressure sensitive adhesive side of the first pressure sensitive adhesive layer comprising a first pressure sensitive adhesive side and a second pressure sensitive adhesive side; and
placing the second support side of the first flexible support layer adjacent to the first pressure sensitive adhesive side of the second pressure sensitive adhesive layer comprising a first pressure sensitive adhesive side and a second pressure sensitive adhesive side.

14. The method of claim 13, further comprising layering a second flexible support layer adjacent to the second pressure sensitive adhesive layer and a third pressure sensitive adhesive layer adjacent to the second flexible support layer, wherein the layering comprises:
placing the first support side of the second flexible support layer comprising a first support side and a second support side adjacent to the second pressure sensitive adhesive side of the second pressure sensitive adhesive layer; and
placing the first pressure sensitive adhesive side of the third pressure sensitive adhesive layer comprising a first pressure sensitive adhesive side and a second pressure sensitive adhesive side adjacent to the second support side of the second flexible support layer.

15. The method of claim 13, wherein the pressure sensitive adhesive layer has a thickness less than 0.08 millimeter.

16. The method of claim 15, wherein the pressure sensitive adhesive layer has a thickness in the range of 0.01 millimeter to 0.02 millimeter.

17. The method of claim 13, wherein the flexible support layer has a thickness less than 0.1 millimeter.

18. The method of claim 17, wherein the flexible support has a thickness in the range of 0.02 millimeter to 0.03 millimeter.

19. A photovoltaic module comprising:
a transparent conductive layer on a substrate;
a first submodule comprising a first plurality of photovoltaic cells connected in series;
a second submodule comprising a second plurality of photovoltaic cells connected in series, wherein the first and second submodules are connected in parallel and contacting the transparent conductive layer through a shared cell;
a strip of tape having a length distributed along a contact region on the first and second submodules, the strip of tape comprising:
a first pressure sensitive adhesive layer comprising a first pressure sensitive adhesive side and a second pressure sensitive adhesive side, wherein the first and second pressure sensitive adhesive sides comprise a pressure sensitive adhesive;
a first flexible support layer comprising a first support side and a second support side and attached adjacent to the second pressure sensitive adhesive side of the first pressure sensitive adhesive layer;
a second pressure sensitive adhesive layer comprising a first pressure sensitive adhesive side and a second pressure sensitive adhesive side, wherein the first and second pressure sensitive adhesive sides comprise the pressure sensitive adhesive, and the first pressure sensitive adhesive side of the second pressure sensitive adhesive layer is attached adjacent to the second support side of the first flexible support layer;
a second flexible support layer comprising a first support side and a second support side and attached adjacent to the second pressure sensitive adhesive side of the second pressure sensitive adhesive layer; and
a third pressure sensitive adhesive layer comprising a first pressure sensitive adhesive side and a second pressure sensitive adhesive side, wherein the first and second pressure sensitive adhesive sides comprise the pressure sensitive adhesive, and the first pressure sensitive adhesive side of the third pressure sensitive adhesive layer is attached adjacent to the second support side of the second flexible support layer.

20. The photovoltaic module of claim 19, further comprising
a lead foil distributed along the length of the strip of tape;
a plurality of parallel bus bars, positioned adjacent and perpendicular to the strip of tape, wherein each one of the plurality of parallel bus bars contacts the lead foil; and
a back support adjacent to the bus bars comprising an access opening for accessing the lead foil.

21. The photovoltaic module of claim 19, wherein at least one of the pressure sensitive adhesive layers of the strip of tape comprises discontinuous stripes.

22. The photovoltaic module of claim 19, wherein the strip of tape comprises a release liner on at least one of the pressure sensitive adhesive layers.
